(19) United States
(12) Patent Application Publication
(10) Pub. No.: US 2025/0062304 A1
(43) Pub. Date: Feb. 20, 2025

(54) SEMICONDUCTOR PACKAGE AND METHOD OF MANUFACTURING THE SAME

(71) Applicant: SAMSUNG ELECTRONICS CO., LTD, SUWON-SI (KR)

(72) Inventors: SEOKGEUN AHN, SUWON-SI (KR); JUHYEON OH, SUWON-SI (KR); DAEHO LEE, SUWON-SI (KR); MINHYUK JUNG, SUWON-SI (KR); EUNHEE JUNG, SUWON-SI (KR)

(21) Appl. No.: 18/749,275

(22) Filed: Jun. 20, 2024

(30) Foreign Application Priority Data
Aug. 14, 2023 (KR) 10-2023-0106421

(51) Int. Cl. H01L 25/18; G02B 6/42; H01L 23/00; H01L 23/48; H01L 23/528; H01L 25/00

(52) U.S. Cl. CPC H01L 25/18; G02B 6/4214; H01L 23/481; H01L 23/5286; H01L 24/08; H01L 24/16; H01L 24/32; H01L 24/73; H01L 25/50; H01L 2224/08145; H01L 2224/08225; H01L 2224/16145; H01L 2224/16227; H01L 2224/32145; H01L 2224/32225; H01L 2224/73204; H01L 2225/06513; H01L 2225/06517; H01L 2225/06544; H01L 2924/12042

(57) ABSTRACT

A semiconductor package includes a package substrate, a semiconductor chip disposed on an upper surface of the package substrate, and an EIC chip disposed on the package substrate and spaced apart from the semiconductor chip in a horizontal direction parallel to the upper surface of the package substrate. The semiconductor package further includes a PIC chip disposed on an upper surface of the EIC chip, wherein a horizontal surface area of the PIC chip is greater than a horizontal surface area of the EIC chip, and wherein a portion of PIC chip protrudes horizontally from the EIC chip. The semiconductor package further includes a reflective portion disposed on a lower surface of the portion of the PIC chip and spaced apart from the EIC chip in the horizontal direction, and an optical fiber connected to the reflective portion and spaced apart from the PIC chip in a vertical direction.

### CROSS-REFERENCE TO RELATED APPLICATION

A claim of priority under 35 USC § 119 is made to Korea patent Application No. 10-2023-0106421, filed on Aug. 14, 2023, in the Korean Intellectual Property Office, the disclosure of which is incorporated by reference herein in its entirety.

### BACKGROUND

The inventive concept relates to a semiconductor package and a method of manufacturing the same, and more particularly, to a semiconductor package including a photonic integrated circuit (PIC) chip.

The advantages of semiconductor packages have been increasingly utilized to improve the functionality of electronic devices and integrate components. Semiconductor packages may allow various types of ICs, such as memory chips or logic chips, to be mounted on package substrates. Recently, in an environment where data traffic has increased in data centers and communication infrastructures, research has been conducted on semiconductor packages containing PIC chips.

### SUMMARY

The inventive concept provides a semiconductor package in which the size of a transparent spacer is relatively small.

The inventive concept also provides a semiconductor package in which a signal distance between an electronic integrated circuit (EIC) and an PIC is reduced.

In addition, the problem to be solved by the inventive concept is not limited to the problems mentioned above, and other problems may be clearly understood by those skilled in the art from the description below.

According to an aspect of the inventive concept, there is provided a semiconductor package including a package substrate, a semiconductor chip disposed on an upper surface of the package substrate, and an electronic integrated circuit chip disposed on the package substrate and spaced apart from the semiconductor chip in a horizontal direction parallel to the upper surface of the package substrate. The semiconductor package further includes a photonic integrated circuit chip disposed on an upper surface of the electronic integrated circuit chip, wherein a horizontal surface area of the photonic integrated circuit chip is greater than a horizontal surface area of the electronic integrated circuit chip, and wherein a portion of photonic integrated circuit chip protrudes horizontally from the electronic integrated circuit chip. The semiconductor package further includes a reflective portion disposed on a lower surface of the portion of the photonic integrated circuit chip and spaced apart from the electronic integrated circuit chip in the horizontal direction, and an optical fiber connected to the reflective portion and spaced apart from the photonic integrated circuit chip in a vertical direction.

According to another aspect of the inventive concept, there is provided a semiconductor package including a package substrate, a semiconductor chip disposed on an upper surface of the package substrate, and a plurality of electronic integrated circuit chips arranged on the package substrate and spaced apart from the semiconductor chip in a horizontal direction. The semiconductor package further includes a photonic integrated circuit chip overlapping the plurality of electronic integrated circuit chips in a vertical direction, wherein a horizontal surface area of the photonic integrated circuit chip is greater than a horizontal surface area of each of the plurality of electronic integrated circuit chips, and a portion of photonic integrated circuit chip protrudes horizontally from the plurality of electronic integrated circuit chips beyond an outer edge of the package substrate. The semiconductor package further includes a reflective portion disposed on a lower surface of the portion of photonic integrated circuit chip and spaced apart from the plurality of electronic integrated circuit chips in the horizontal direction, and an optical fiber connected to the reflective portion and spaced apart from the photonic integrated circuit chip in the vertical direction. The plurality of electronic integrated circuit chips are electrically connected to the photonic integrated circuit chip.

According to another aspect of the inventive concept, there is provided a semiconductor package including a package substrate, a semiconductor chip disposed on an upper surface of the package substrate, and a plurality of electronic integrated circuit chips arranged on the package substrate, spaced apart from the semiconductor chip in a horizontal direction, and electrically connected to the semiconductor chip through the package substrate. The semiconductor package further includes a photonic integrated circuit chip overlapping the plurality of electronic integrated circuit chips in a vertical direction, the photonic integrated circuit chip including an opto-electrical conversion unit and have a horizontal surface area that is greater than a horizontal surface area of each of the plurality of electronic integrated circuit chips, wherein a portion of the photonic integrated circuit chip protrudes from the plurality of electronic integrated circuit chips beyond an outer edge of the package substrate. The semiconductor package further includes a reflective portion disposed on a lower surface of portion the photonic integrated circuit chip protruding beyond the outer edge of the package substrate, the reflective portion including a groove spacer including a groove, a transparent spacer, and a plurality of mirrors. The semiconductor package further includes an optical fiber connected to the groove of the groove spacer of the reflective portion and spaced apart from the photonic integrated circuit chip in the vertical direction. The plurality of electronic integrated circuit chips are electrically connected to the photonic integrated circuit chip through through-vias located in the plurality of electronic integrated circuit chips.

### BRIEF DESCRIPTION OF THE DRAWINGS

Embodiments will be more clearly understood from the following detailed description taken in conjunction with the accompanying drawings in which:

FIG. 1 is a perspective view schematically illustrating a semiconductor package according to an embodiment;

FIG. 2 is a plan view of the semiconductor package of FIG. 1;

FIG. 3 is a schematic cross-sectional view of the semiconductor package taken along line A-A′ of FIG. 2;

FIG. 4 is an enlarged view of the portion “EX” of the semiconductor package of FIG. 3 according to an embodiment;

FIG. 5 is an enlarged view of the portion “EX” of the semiconductor package of FIG. 3 according to an embodiment;

FIG. 6 is an enlarged view of the portion “EX” of the semiconductor package of FIG. 3 according to an embodiment;

FIG. 7 is a perspective view schematically illustrating a semiconductor package according to an embodiment;

FIG. 8 is a schematic cross-sectional view of a partially cutout portion of the semiconductor package of FIG. 7;

FIG. 9 is a plan view schematically illustrating a semiconductor package according to an embodiment;

FIG. 10 is a schematic cross-sectional view of the semiconductor package taken along line B-B′ of FIG. 9;

FIG. 11 is a plan view schematically illustrating a semiconductor package according to an embodiment; and

FIGS. 12 to 17 are diagrams for reference in describing a sequential process of a method of manufacturing a semiconductor package according to an embodiment.

### DETAILED DESCRIPTION OF THE EMBODIMENTS

The embodiments may be modified in various forms and various embodiments may be provided, and thus, some embodiments are illustrated in the drawings and described in detail. However, the present embodiments are not intended to be limited to a specific disclosure form.

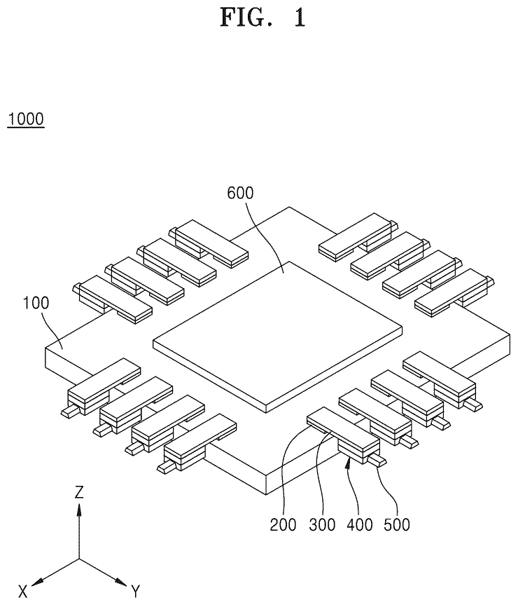

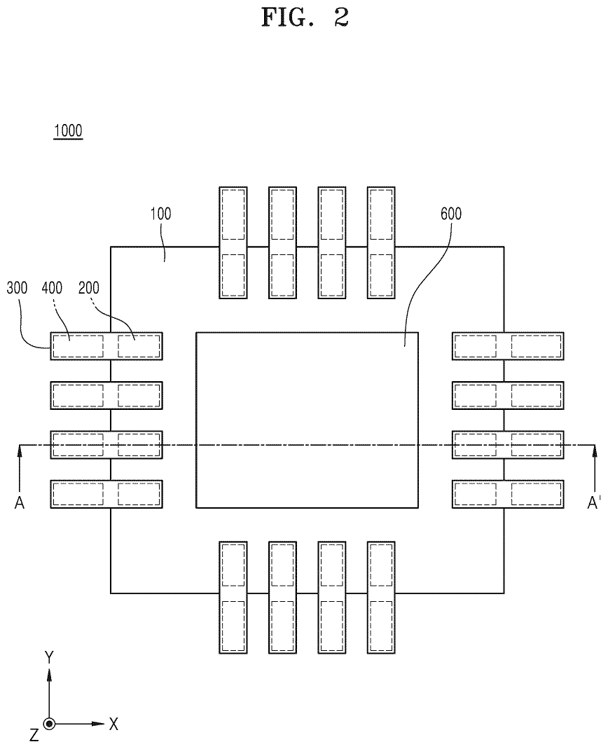

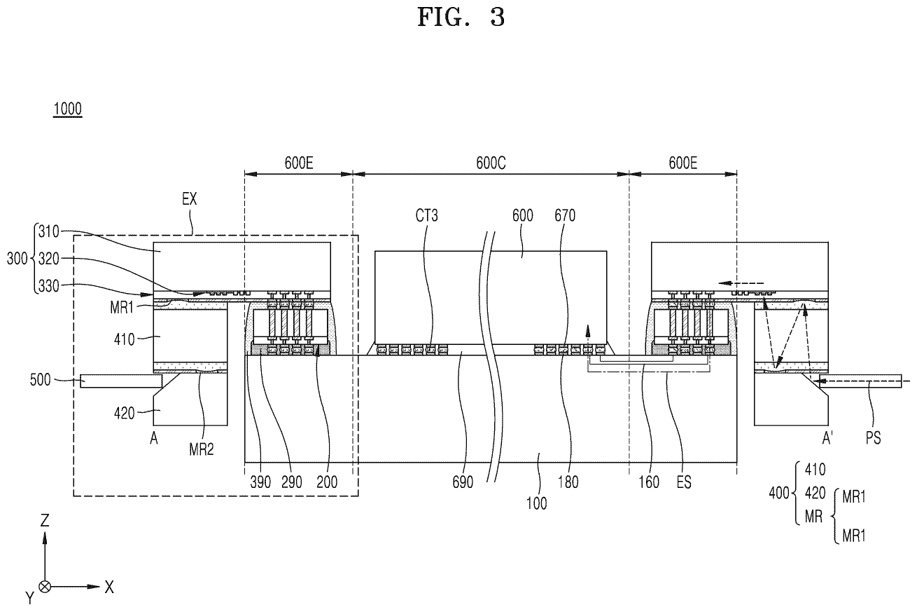

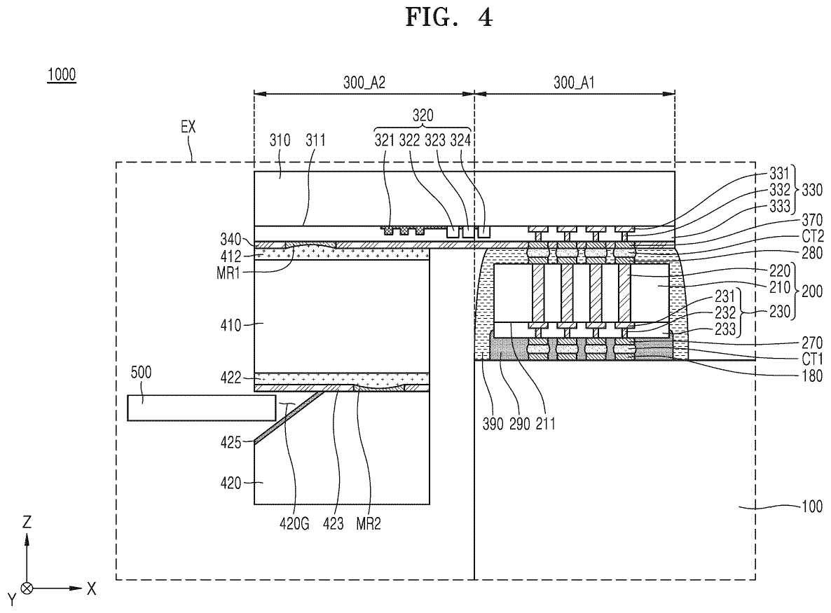

FIG. 1 is a perspective view schematically illustrating a semiconductor package 1000 according to an embodiment. FIG. 2 is a plan view of the semiconductor package 1000 of FIG. 1. FIG. 3 is a schematic cross-sectional view of the semiconductor package 1000 taken along line A-A′ of FIG. 2. FIG. 4 is an enlarged view of a portion “EX” of the semiconductor package 1000 of FIG. 3.

Referring to FIGS. 1 to 4, the semiconductor package 1000 includes a package substrate 100, a semiconductor chip 600, an electronic integrated circuit (EIC) chip 200, a photonic integrated circuit (PIC) chip 300, a reflective portion 400, and an optical fiber 500.

Hereinafter, unless otherwise defined, a direction parallel to an upper surface of the package substrate 100 is defined as a first direction (an X direction), a direction perpendicular to the upper surface of the package substrate 100 is defined as a vertical direction (a Z direction), and a direction perpendicular to the first direction (the X direction) and the vertical direction (the Z direction) is defined as a second direction (a Y direction).

The package substrate 100 of the semiconductor package 1000 may be, for example, a printed circuit board (PCB). The package substrate 100 may include at least one material selected from a phenol resin, an epoxy resin, and polyimide. For example, the package substrate 100 may include at least one selected from polyimide, flame retardant 4 (FR-4), tetrafunctional epoxy, polyphenylene ether, epoxy/polyphenylene oxide, bismaleimide triazine (BT), thermount, cyanate ester, and liquid crystal polymer.

The package substrate 100 may include contact pads 180 located on upper and lower surfaces of the package substrate 100. The contact pads 180 may be a portion of a circuit interconnection patterned after coating the upper and lower surfaces of the package substrate 100 with copper (Cu) foil. In detail, each contact pad 180 may be a region of a circuit interconnection that is not covered by a solder resist layer and exposed externally.

In some embodiments, the contact pads 180 may each include copper, nickel, stainless steel, or beryllium copper. An internal interconnection 160 may be formed within the package substrate 100 to electrically connect the contact pads 180 to each other.

In FIG. 2, the contact pads 180 of the package substrate 100 are shown as being located on the upper surface of the package substrate 100. However, the inventive concept is not limited thereto, and as mentioned above contact pads 180 may also be located on the lower surface of the package substrate 100.

The package substrate 100 may include a center region 600C and an edge region 600E. The center region 600C may include the center of the package substrate 100, and the edge region 600E may surround the center region 600C and may include a regions adjacent the outer edges of the upper surface of the package substrate 100. In some embodiments, the semiconductor chip 600 may be located in the center region 600C of the package substrate 100, and the EIC chip 200 may be located in the edge region 600E of the package substrate 100.

The semiconductor chip 600 of the semiconductor package 1000 may include an active surface and an inactive surface opposite to the active surface. In some embodiments, the semiconductor chip 600 may include an application specific integrated circuit (ASIC).

In some embodiments, the semiconductor chip 600 may be mounted on the package substrate 100 with the active surface of the semiconductor chip 600 facing down. That is, a contact pad 670 of the semiconductor chip 600 may be located on the active surface of the semiconductor chip 600. The contact pad 670 of the semiconductor chip 600 may be electrically connected to the contact pad 180 located on the upper surface of the package substrate 100 through a connection terminal CT3. In some embodiments, the connection terminal CT3 may include solder balls and/or solder bumps. In some embodiments, the contact pads 670 and 180 of the semiconductor chip 600 and the package substrate 100 and the connection terminal CT3 may be surrounded by an underfill layer 690.

In some embodiments, a plurality of various types of individual devices may be located on the active surface of the semiconductor chip 600. For example, the plurality of individual devices may include various microelectronic devices, such as a complementary metal-oxide semiconductor (CMOS) transistor, a metal-oxide-semiconductor filed effect transistor (MOSFET), a system large scale integration (LSI), an image sensor, such as a CMOS imaging sensor (CIS), a micro-electro-mechanical system (MEMS), active devices, and passive devices.

The EIC chip 200 of the semiconductor package 1000 may be disposed on the upper surface of the package substrate 100. The EIC chip 200 may be spaced apart from the semiconductor chip 600 in the horizontal direction. The EIC chip 200 may be disposed on the upper surface of the package substrate 100 so that an active surface 211 of a first substrate 210 of the EIC chip 200 faces the package substrate 100.

For example, the EIC chip 200 may be located in the edge region 600E of the package substrate 100 and closer to the outer edge of the upper surface of the package substrate 100 than to a center point of the upper surface of the package substrate 100.

The EIC chip 200 may include the first substrate 210, a first interconnection structure 230, and a first through-via 220 extending in the EIC chip 200 from the active surface 211 of the first substrate 210.

In some embodiments, the EIC chip 200 may include a plurality of devices used for the PIC chip 300 to interface with other devices. The devices of the EIC chip 200 may be located on the active surface 211 of the first substrate 210. For example, the EIC chip 200 may include CMOS drivers, transimpedance amplifiers, etc. to perform functions, such as controlling high-frequency signaling of the PIC chip 300.

In some embodiments, the first substrate 210 of the EIC chip 200 may include a semiconductor material, such as silicon (Si). Alternatively, the first substrate 210 may include a semiconductor material, such as germanium (Ge).

The first interconnection structure 230 of the EIC chip 200 may include a plurality of first interconnection patterns 231, a plurality of first interconnection vias 232 respectively connected to the first interconnection patterns 231, and a first insulating layer 233 surrounding the first interconnection patterns 231 and the interconnection vias 232. In some embodiments, the first interconnection structure 230 may have a multi-layer interconnection structure including the first interconnection patterns 231 and the first interconnection vias 232 located at different vertical levels.

In some embodiments, the first through-via 220 may be electrically connected to a plurality of devices on the first interconnection structure 230 and/or the active surface 211 of the first substrate 210. Accordingly, the EIC chip 200 may be electrically connected to the PIC chip 300 by the first through-via 220.

In some embodiments, the EIC chip 200 may further include an upper pad 280 and a lower pad 270. The lower pad 270 may be disposed on the lower surface of the EIC chip 200 and may be electrically connected to the first interconnection pattern 231 and/or the first interconnection via 232. The lower pad 270 of the EIC chip 200 may be electrically connected to the contact pad 180 of the package substrate 100 through a connection terminal CT1.

In some embodiments, the semiconductor package 1000 may further include a first underfill layer 290 surrounding the lower pad 270 of the EIC chip 200 and the corresponding contact pad 180 of the package substrate 100. In detail, the first underfill layer 290 may be located between the lower surface of the EIC chip 200 and the upper surface of the package substrate 100 and surround a portion of a side surface of the EIC chip 200, the lower pad 270, the connection terminal CT1, and the contact pad 180. In some embodiments, the first underfill layer 290 may include a non-conductive film (NCF).

The PIC chip 300 of the semiconductor package 1000 may include a second substrate 310, a second interconnection structure 330, and an opto-electrical conversion unit 320. The PIC chip 300 may be located on the upper surface of the EIC chip 200. For example, the PIC chip 300 may be disposed on the EIC chip 200 so that an active surface 311 of the second substrate 310 of the PIC chip 300 faces the EIC chip 200.

The PIC chip 300 may input and output a photonic signal PS. In detail, the PIC chip 300 may convert an electrical signal ES into a photonic signal PS and transfer the photonic signal PS along the optical fiber 500, and may convert a photonic signal into an electrical signal ES and transfer the electrical signal ES to the semiconductor chip 600.

In FIG. 3, the dashed line arrow indicates a path along which the photonic signal PS moves and the short dash-long dash line arrow indicates a path along which the electrical signal ES moves.

In FIG. 3, the dashed line arrow and the short dash-long dash line arrow indicate a path through which the photonic signal PS is input. However, the dotted line arrow and the dashed line arrow may also be depicted in reverse directions to indicate that the photonic signal PS may be output.

The second substrate 310 of the PIC chip 300 may include a semiconductor material, such as silicon (Si). Alternatively, the second substrate 310 may include a semiconductor material, such as germanium (Ge).

The opto-electrical conversion unit 320 of the PIC chip 300 may convert the photonic signal PS into the electrical signal ES and the electrical signal ES into the photonic signal PS. For example, the opto-electrical conversion unit 320 may include a grating coupler 321, a photo detector 322, a laser diode 323, and a modulator 324.

The grating coupler 321 may be a path through which the photonic signal PS input through the reflective portion 400 moves to the photo detector 322 and may be a path through which the photonic signal PS emitted from the laser diode 323 is output to the reflective portion 400. For example, the grating coupler 321 may provide a path for the photonic signal PS to move in a direction parallel to the lower surface of the second substrate 310.

In the process of inputting the photonic signal PS to the PIC chip 300, the photo detector 322 may detect the photonic signal PS input to the PIC chip 300. The photonic signal PS may be detected by the photo detector 322 and converted into the electrical signal ES. The electrical signal ES converted by the photo detector 322 may be transmitted to the devices on the active surface 311 of the second substrate 310 of the PIC chip 300.

In the process of outputting the photonic signal by the PIC chip 300, the devices on the active surface 311 of the second substrate 310 of the PIC chip 300 may transfer the electrical signal ES to the modulator 324. The modulator 324 may input a signal into light emitted by the laser diode 323 according to the electrical signal ES and convert the electrical signal ES into the photonic signal PS.

Although in FIG. 4 the opto-electrical conversion unit 320 is shown to be embedded in the second insulating layer 333, the inventive concept is not limited thereto, and the opto-electrical conversion unit 320 may instead be covered with an oxide layer that is distinguished from the second insulating layer 333. That is, the oxide layer may be formed on one side of the second insulating layer 333, and the opto-electrical conversion unit 320 may be located inside the oxide layer.

The second interconnection structure 330 of the PIC chip 300 may include a plurality of second interconnection patterns 331, a plurality of second interconnection vias 332 respectively connected to the second interconnection patterns 331, and a second insulating layer 333 surrounding the second interconnection patterns 331 and the second interconnection vias 332. In some embodiments, the second interconnection structure 330 may have a multi-layer interconnection structure including the second interconnection patterns 331 and the second interconnection vias 332 located at different vertical levels.

In some embodiments, the PIC chip 300 may further include a lower pad 370 and a passivation layer 340 surrounding the lower pad 370. The lower pad 370 may be disposed on a lower surface of the second interconnection structure 330 of the PIC chip 300 and may be electrically connected to the second interconnection patterns 331 and/or the second interconnection vias 332. The lower pad 370 of the PIC chip 300 may be electrically connected to the upper pad 280 of the EIC chip 200 through a connection terminal CT2.

In some embodiments, the semiconductor package 1000 may further include a second underfill layer 390 surrounding the upper pad 280 of the EIC chip 200 and the lower pad 370 of the PIC chip 300. In detail, the second underfill layer 390 may be located between the lower surface of the PIC chip 300 and the upper surface of the package substrate 100 and surround the EIC chip 200, the first underfill layer 290, the connection terminal CT2, and the lower pad 370.

In some embodiments, a constituent material of the second underfill layer 390 may be different than that of the first underfill layer 290. In some embodiments, even if the constituent material of the second underfill layer 390 is the same as the constituent material of the first underfill layer 290, the curing time of the second underfill layer 390 may be different from the curing time of the first underfill layer 290, so that a boundary between the second underfill layer 390 and the first underfill layer 290 may be apparent.

In some embodiments, an area of the PIC chip 300 may be different from that of the EIC chip 200. An area occupied by the PIC chip 300 may be greater than that of the EIC chip 200. In this specification, “area” may refer to a two-dimensional size of the PIC chip 300 and the EIC chip 200 in a horizontal plan. To put it another way, a horizontal surface area of the PIC chip 300 may be greater than a horizontal surface area of the EIC chip 200.

For example, the PIC chip 300 may protrude to the outside of the EIC chip 200 planarly from the upper surface of the EIC chip 200. Even if the PIC chip 300 is stacked on top of the EIC chip 200, the PIC chip 300 may have an area greater than that of the EIC chip 200 and may protrude to the outside of the EIC chip 200.

In some embodiments, the PIC chip 300 may protrude to the outside of the package substrate 100 planarly. For example, the EIC chip 200 may be located at the edge region of the package substrate 100, and the PIC chip 300 may be located to protrude from the upper surface of the EIC chip 200 toward the side surface of the package substrate 100 adjacent to the EIC chip 200.

In some embodiments, the PIC chip 300 may include a first region 300_A1 and a second region 300_A2. A region in which the PIC chip 300 overlaps the package substrate 100 in the vertical direction (the Z direction) is the first region 300_A1, and a region in which the PIC chip 300 extends beyond the edge of the package substrate 100 in the vertical direction (the Z direction) may be the second region 300_A2. That is, the second region 300_A2 of the PIC chip 300 may be a region in which the PIC chip 300 protrudes beyond the package substrate 100 in a planar and horizontal direction.

For example, the second interconnection patterns 331 and the second interconnection vias 332 may be located on the first region 300_A1 of the PIC chip 300, and the grating coupler 321 of the opto-electrical conversion unit 320 may be located on the second region 300_A2 of the PIC chip 300.

In some embodiments, a vertical level of the semiconductor chip 600 may be lower than or equal to a vertical level of the PIC chip 300. The vertical level of the semiconductor chip 600 may be greater than the vertical level of the EIC chip 200. In this specification, the “vertical level” refers to a separation distance from the lower surface of the package substrate in the vertical direction (the Z direction).

The first interconnection patterns 231, the first interconnection vias 232, the second interconnection patterns 331, and the second interconnection vias 332 may include metal materials, for example, aluminum, copper, or tungsten. In some embodiments, the first interconnection patterns 231, the first interconnection vias 232, the second interconnection patterns 331, and the second interconnection vias 332 may include a barrier film for interconnection and a metal layer for interconnection. The barrier film for interconnection may include metal, metal nitride, or alloy. The metal layer for interconnection may include at least one metal selected from W, Al, Ti, Ta, Ru, Mn, or Cu.

In some embodiments, the semiconductor package 1000 may include a plurality of EIC chips 200 and a plurality of PIC chips 300. The EIC chips 200 and the PIC chips 300 respectively located on the EIC chips 200 may be arranged to surround the semiconductor chip 600 as shown, for example in FIGS. 1 and 2.

In some embodiments, each side of the semiconductor chip 600 may face at least one EIC chip and at least one PIC chip. For example, the four sides of the semiconductor chip 600 may each face at least one EIC chip 200 and at least one PIC chip 300. Although in FIGS. 1 and 2 four EIC chips 200 and four PIC chips 300 face each other on each side of the semiconductor chip 600, the number of EIC chips 200 and PIC chips 300 is not limited thereto.

The reflective portion 400 of the semiconductor package 1000 may be disposed on the lower surface of the PIC chip 300. The reflective portion 400 may be apart from the EIC chip in the horizontal direction. The reflective portion 400 may be disposed on the lower surface of a region of the PIC chip 300 that protrudes out of the EIC chip 200. In some embodiments, the reflective portion 400 may be disposed on the lower surface of the second region 300_A2 of the PIC chip 300.

In some embodiments, the area of the reflective portion 400 may be less than the area of the PIC chip 300. Further, the sum of the area of the reflective portion 400 and the area of the EIC chip 200 may be less than the area of the PIC chip 300.

The reflective portion 400 may be configured to change a path of the photonic signal PS. For example, the reflective portion 400 may include a transparent spacer 410, a groove spacer 420, and a plurality of mirrors MR.

The transparent spacer 410 may be attached to a lower surface of the PIC chip 300. The transparent spacer 410 may be attached to a lower surface of a passivation layer 340 of the PIC chip 300 through an adhesive layer 412. The transparent spacer 410 and the adhesive layer 412 may include a material through which the photonic signal PS passes. For example, the transparent spacer 410 may include at least one of glass and quartz.

The photonic signal PS incident on the transparent spacer 410 may change in path due to reflection by the mirrors MR and may enter the grating coupler 321 of the PIC chip 300. That is, the mirrors MR may be arranged under incident/reflection conditions such that the optical fiber 500 inputs the photonic signal PS transmitted to the reflective portion 400 to the PIC chip 300. In some embodiments, the mirrors MR may be manufactured using nanoimprint lithography.

In some embodiments, the mirrors MR may be located above and below the transparent spacer 410. For example, the mirrors MR may include a first mirror MR1 and a second mirror MR2. The first mirror MR1 may be located above the transparent spacer 410, and the second mirror MR2 may be located below the transparent spacer 410. For example, the first mirror MR1 may be located between the PIC chip 300 and the transparent spacer 410 and may be surrounded by the passivation layer 340 of the PIC chip 300. The second mirror MR2 may be located between the transparent spacer 410 and the groove spacer 420 and may be surrounded by a passivation layer 423 of the groove spacer 420.

The groove spacer 420 may be attached to a lower surface of the transparent spacer 410. At least one mirror and the passivation layer 423 surrounding the mirror may be located on an upper surface of the groove spacer 420. The groove spacer 420 may be attached to the lower surface of the transparent spacer 410 through an adhesive layer 422 so that the passivation layer 423 faces the transparent spacer 410. In some embodiments, the adhesive layer 422 may include a transparent material through which the photonic signal PS passes.

The groove spacer 420 may include a groove 420G on one side into which the optical fiber 500 is inserted. For example, the groove 420G may be V-shaped. In some embodiments, the groove spacer 420 may include an opaque material that does not allow the photonic signal PS to pass therethrough. For example, the material of the groove spacer 420 may be different than the material of the transparent spacer 410.

In some embodiments, a reflective layer 425 may be located on one surface of the groove spacer 420 that defines the groove 420G. In some embodiments, the reflective layer 425 may reflect the photonic signal PS like a mirror. In some embodiments, the reflective layer 425 may have a refractive index that is different from that of the groove spacer 420. For example, light incident on the reflective layer 425 may be totally reflected from a boundary between the groove spacer 420 and the reflective layer 425 and may enter the transparent spacer 410.

In some embodiments, the optical fiber 500 inserted into the groove 420G may transmit the photonic signal PS to the reflective layer 425, and the photonic signal PS may be reflected from the reflective layer 425, may pass through the transparent spacer 410, may be reflected from the first mirror MR1, and enter the second mirror MR2. The photonic signal PS incident on the second mirror MR2 may be reflected again, and the photonic signal PS may be input to the PIC chip 300. In the case of outputting the photonic signal PS from the PIC chip 300, the photonic signal PS may be received by the optical fiber 500 by following the previously described path in reverse order.

The optical fiber 500 of the semiconductor package 1000 may be connected to the reflective portion 400. For example, the optical fiber 500 may be inserted into the groove 420G of the reflective portion 400 at the outside of the package substrate 100. The optical fiber 500 may be spaced apart from the PIC chip 300 in the vertical direction (the Z direction).

The optical fiber 500 may transmit the photonic signal PS to the reflective portion 400 or may receive the photonic signal PS from the reflective portion 400. In some embodiments, the semiconductor package 1000 may include a plurality of optical fibers 500, some of the optical fibers 500 may transmit the photonic signal PS, and some of the optical fibers 500 may receive the photonic signal PS.

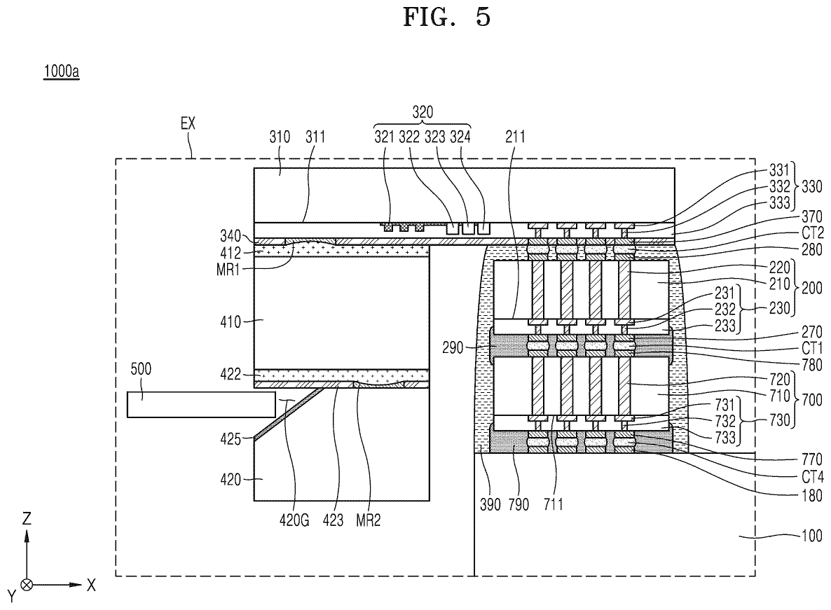

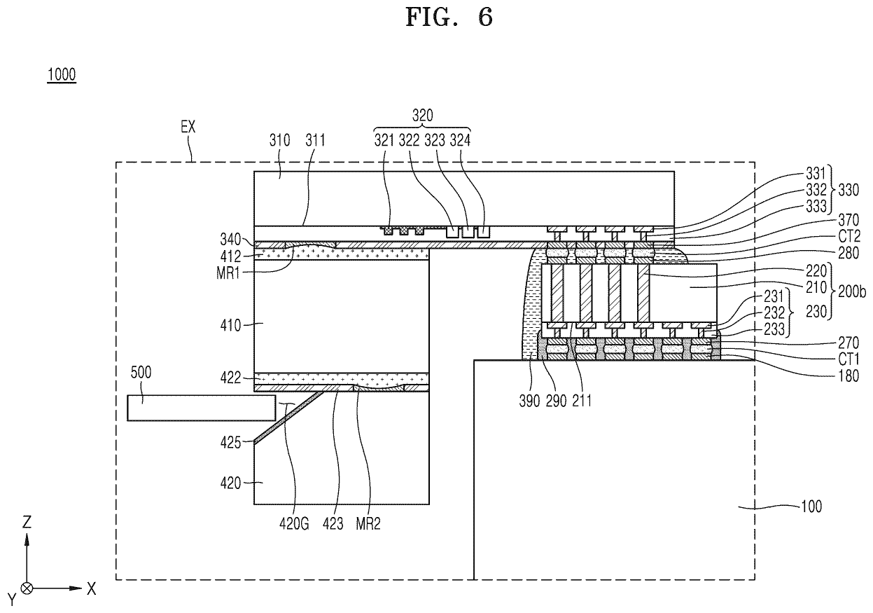

FIG. 5 is an enlarged view of the portion “EX” shown in FIG. 3 of a semiconductor package 1000a according to another embodiment. FIG. 6 is an enlarged view of the portion “EX” shown in FIG. 3 of a semiconductor package 1000b according to yet another embodiment.

Most of the components constituting the semiconductor packages 1000a and 1000b described below and the materials constituting the components are substantially the same as or similar to those previously described above with reference to FIG. 4. Therefore, for convenience of description, the differences between the semiconductor packages 1000a and 1000b of FIGS. 5 and 6 and the semiconductor package 1000 of FIG. 4 are mainly described.

Referring to FIG. 5, the semiconductor package 1000a may further include an IC chip 700. The IC chip 700 may be of a different type from those of the PIC chip 300 and the EIC chip 200. That is, the IC chip 700 may not convert photonic signals and electrical signals or may not interface with PIC chips. For example, the IC chip 700 may be a type of IC chip, such as a voltage regulator IC chip or a digital signal processor IC chip. A plurality of devices of the IC chip 700 may be located on an active surface 711 of a third substrate 710.

The IC chip 700 may be located between the EIC chip 200 and the package substrate 100. The EIC chip 200 may be stacked on top of the EIC chip 200. The IC chip 700 may be apart from the PIC chip 300 with the EIC chip 200 therebetween. The IC chip 700 may include a third substrate 710, a third interconnection structure 730, and a third through-via 720 extending in the IC chip 700 from the active surface 711 of the third substrate 710.

In some embodiments, the third substrate 710 of the IC chip 700 may include a semiconductor material, such as silicon (Si). Alternatively, the third substrate 710 may include a semiconductor material, such as germanium (Ge).

The third interconnection structure 730 of the IC chip 700 may include a plurality of third interconnection patterns 731, a plurality of third interconnection vias 732 respectively connected to the third interconnection patterns 731, and a third insulating layer 733 surrounding the third interconnection patterns 731 and the third interconnection vias 732. In some embodiments, the third interconnection structure 730 may have a multi-layer interconnection structure including the third interconnection patterns 731 and the third interconnection vias 732 located at different vertical levels.

In some embodiments, the third through-via 720 may be electrically connected to a plurality of devices on the third interconnection structure 730 and/or the active surface 711. Accordingly, the IC chip 700 may be electrically connected to the EIC chip 200 by the third through-via 720.

In some embodiments, the IC chip 700 may further include an upper pad 780 and a lower pad 770. The lower pad 770 may be disposed on a lower surface of the IC chip 700 and may be electrically connected to the third interconnection pattern 731 and/or the third interconnection via 732. The upper pad 780 may be disposed on the upper surface of the IC chip 700 and may be electrically connected to the third through-via 720.

The lower pad 770 of the IC chip 700 may be electrically connected to the corresponding contact pad 180 of the package substrate 100 through a connection terminal CT4. The upper pad 780 of the IC chip 700 may be electrically connected to the lower pad 270 of the EIC chip 200 through the connection terminal CT1.

Referring to FIG. 6, a portion of an EIC chip 200b of the semiconductor package 1000b may not overlap the PIC chip 300 in the vertical direction (the Z direction). That is, the EIC chip 200b may include a third region that overlaps the PIC chip 300 in the vertical direction (the Z direction) and a fourth region that does not overlap the PIC chip 300 in the vertical direction. The third region of the EIC chip 200b may be a region located below the first region of the PIC chip 300.

In some embodiments, the upper pad 280 of the EIC chip 200b may be located on the third region of the EIC chip 200b. That is, the upper pad 280 may be formed in a region of the upper surface of the EIC chip 200b that overlaps the PIC chip 300 in the vertical direction (the Z direction). The lower pad 270 of the EIC chip 200b may be formed on the entire lower surface of the EIC chip 200b. The lower pad 270 may be formed in the third and fourth regions of the EIC chip 200b.

In some embodiments, a portion of the second underfill layer 390 may be formed on the upper surface of the EIC chip 200b. Because the second underfill layer 390 surrounds a pad located between the PIC chip 300 and the EIC chip 200b, one side of the second underfill layer 390 may be located on an upper surface of the EIC chip 200b in the process of forming the second underfill layer 390. That is, one side of the EIC chip 200b may not be covered by the second underfill layer 390.

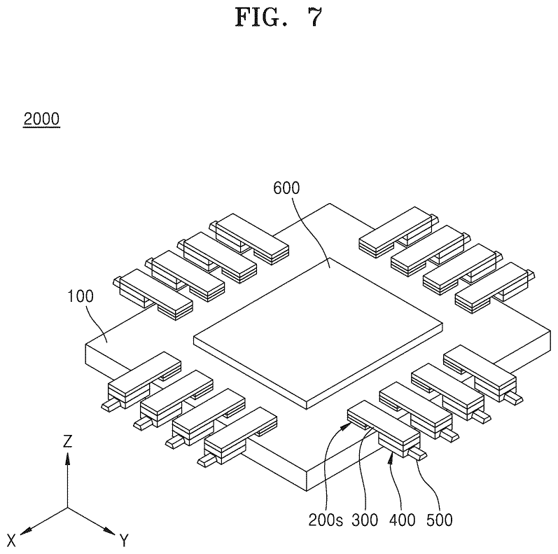

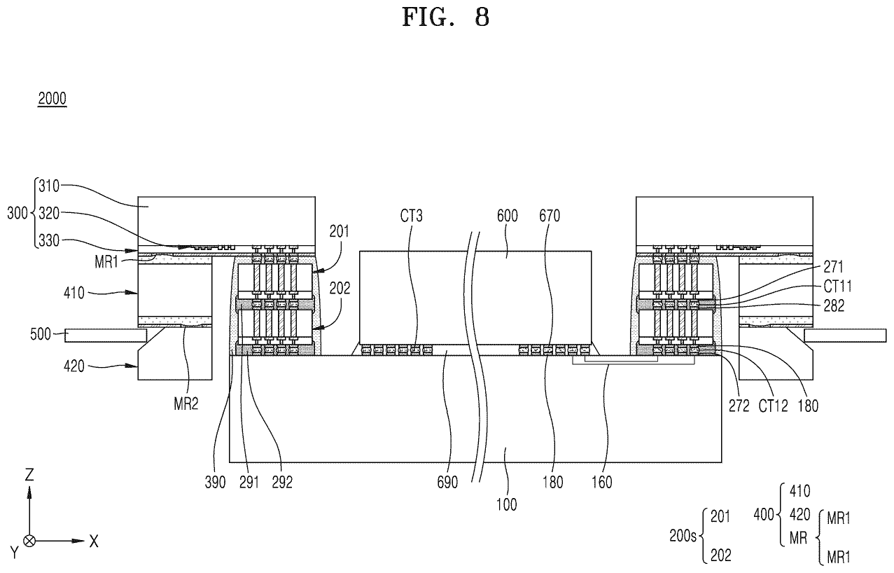

FIG. 7 is a perspective view schematically illustrating a semiconductor package 2000 according to an embodiment. FIG. 8 is a schematic cross-sectional view of a partially cutout portion of the semiconductor package 2000 of FIG. 7. For example, FIG. 8 is a cross-sectional view of the semiconductor package 2000 of FIG. 7 taken along a line similar to the line A-A′ of FIG. 2.

Most of the components constituting the semiconductor package 2000 described below and the materials constituting the components are substantially the same as or similar to those previously described above with reference to FIGS. 1-4. Therefore, for convenience of description, the differences between the semiconductor package 2000 of FIGS. 7 and 8 and the semiconductor package 1000 of FIGS. 1-4 described above are mainly described below.

Referring to FIGS. 7 and 8, the semiconductor package 2000 may include the package substrate 100, a plurality of EIC chips 200s, the PIC chip 300, the reflective portion 400, the optical fiber 500, and a semiconductor chip 600. Hereinafter, the EIC chips 200s refer to EIC chips connected to one PIC chip 300.

The EIC chips 200s may be located on the package substrate 100 and may be spaced apart from the semiconductor chip 600 in the horizontal direction. For example, the EIC chips 200s may be located near the outer edge of the upper surface of the package substrate 100. Each of the EIC chips 200s may be substantially the same as the EIC chip 200 of FIGS. 1-4 described above.

The EIC chips 200s may include a first EIC chip 201 and a second EIC chip 202. The second EIC chip 202 may be located on the upper surface of the package substrate 100, and the first EIC chip 201 may be located on an upper surface of the second EIC chip 202. For example, the first EIC chip 201 and the second EIC chip 202 may be stacked in the vertical direction (the Z direction).

In some embodiments, the first EIC chip 201 and the second EIC chip 202 each include a through-via, the first EIC chip 201 may be electrically connected to the PIC chip 300 through the through-via, and the second EIC chip 202 may be electrically connected to the first EIC chip 201 through the through-via.

In some embodiments, a lower pad 272 of the second EIC chip 202 may be electrically connected to the contact pad 180 of the package substrate 100 through a connection terminal CT12. Accordingly, the second EIC chip 202 may transmit and receive electrical signals to and from the semiconductor chip 600 through the package substrate 100. In some embodiments, a fourth underfill layer 292 may be further provided to protect the lower pad 272 of the second EIC chip 202, the contact pad 180 of the package substrate 100, and the connection terminal CT12.

In some embodiments, a lower pad 271 of the first EIC chip 201 may be electrically connected to an upper pad 282 of the second EIC chip 202 through a connection terminal CT11. Accordingly, the first EIC chip 201 may transmit and receive electrical signals to and from the semiconductor chip 600 through the second EIC chip 202 and the package substrate 100. In some embodiments, a third underfill layer 291 may be further provided to protect the lower pad 271 of the first EIC chip 201, the upper pad 282 of the second EIC chip 202, and the connection terminal CT11.

Although in FIG. 8 the first EIC chip 201 and the second EIC chip 202 are shown to have the same horizontal surface areas, the first EIC chip 201 and the second EIC chip 202 are not limited in this manner. For example, a horizontal surface area of the first EIC chip 201 may be greater than a horizontal surface area of the second EIC chip 202 so that the first EIC chip 201 may protrude horizontally from the upper surface of the second EIC chip 202.

The PIC chip 300 may overlap the EIC chips 200s in the vertical direction (the Z direction). For example, the PIC chip 300 may vertically overlap at least two EIC chips 200s. The PIC chip 300 may include a region that does not overlap the EIC chips 200s. The reflective portion 400 may be located on a region of the lower surface of the PIC chip 300 that does not overlap the EIC chips 200s.

In some embodiments, the PIC chip 300 may be disposed on an upper surface of the uppermost EIC chip among the stacked EIC chips 200s. For example, the PIC chip 300 may be in direct contact with the uppermost EIC chip.

In some embodiments, the PIC chip 300 may be located on the upper surface of the first EIC chip 201. The PIC chip 300 may have a horizontal surface area greater than that of the first EIC chip 201 so that the PIC chip 300 may protrude in an horizontal direction from the upper surface of the first EIC chip 201. For example, the PIC chip 300 may be disposed on the upper surface of the first EIC chip 201 so that one side of the PIC chip 300 protrudes beyond the outer edge of the package substrate 100.

In some embodiments, a vertical level of the upper surface of the semiconductor chip 600 may be lower than a vertical level of the upper surface of the PIC chip 300 and greater than a vertical level of the upper surface of the second EIC chip 202.

In some embodiments, the second underfill layer 390 may be located between the lower surface of the PIC chip 300 and the upper surface of the package substrate 100 to surround the first EIC chip 201 and the second EIC chip 202.

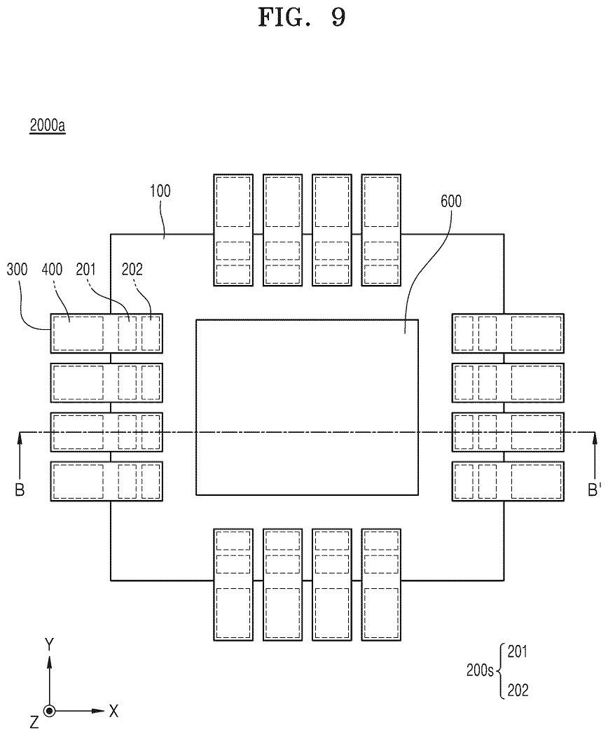

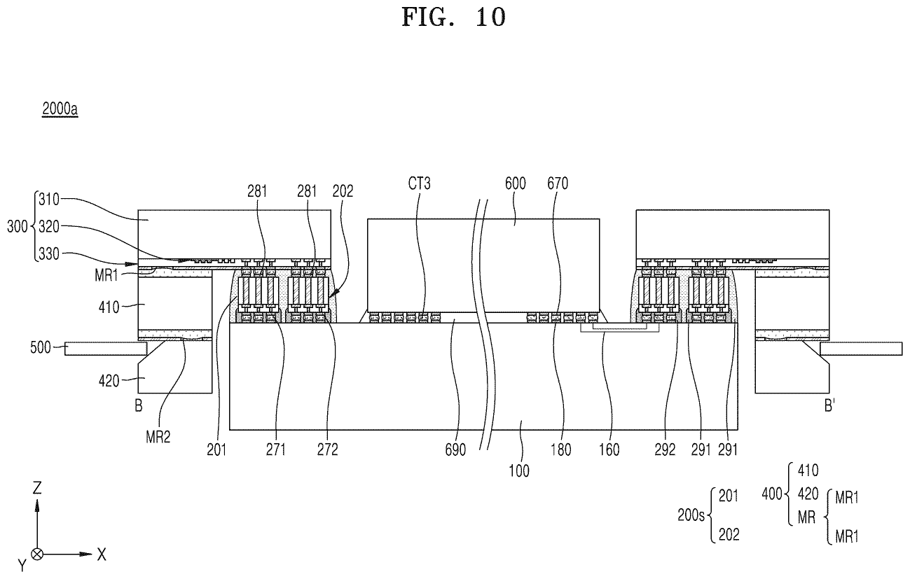

FIG. 9 is a plan view schematically illustrating a semiconductor package 2000a according to an embodiment. FIG. 10 is a schematic cross-sectional view of the semiconductor package 2000a of FIG. 9, taken along line B-B′ of FIG. 9.

Most of the components constituting the semiconductor package 2000a described below and the materials constituting the components are substantially the same as or similar to those previously described above with reference to FIG. 8. Therefore, for convenience of description, the differences between the semiconductor package 2000a of FIGS. 9 and 10 and the semiconductor package 2000 of FIG. 8 described above are mainly described.

The EIC chips 200s may be arranged to be spaced apart in the horizontal direction. For example, a vertical level of the upper surface of each of the EIC chips 200s may be the same, and each of the plurality of EIC chips 200s may be located on the upper surface of the package substrate 100.

The EIC chips 200s may include the first EIC chip 201 and the second EIC chip 202. The first EIC chip 201 and the second EIC chip 202 may be electrically connected to one PIC chip 300. The first EIC chip 201 may be spaced apart from the second EIC chip 202 in the first direction (the X direction) or the second direction (the Y direction). Although in FIG. 10 the first EIC chip 201 and the second EIC chip 202 are shown to be spaced apart in the first direction (the X direction), the inventive concept is not limited thereto.

In some embodiments, the first EIC chip 201 and the second EIC chip 202 may each include a through-via, and the first EIC chip 201 and the second EIC chip 202 may be electrically connected to the PIC chip 300 through the through-vias.

In some embodiments, the lower pad 271 of the first EIC chip 201 and the lower pad 272 of the second EIC chip 202 may be electrically connected to the contact pad 180 of the package substrate 100 through a connection terminal. Accordingly, the first EIC chip 201 and the second EIC chip 202 may transmit and receive electrical signals to and from the semiconductor chip 600 through the package substrate 100.

In some embodiments, the semiconductor package 2000a may further include a third underfill layer 291 located between the first EIC chip 201 and the package substrate 100 and a fourth underfill layer 292 located between the second EIC chip 202 and the package substrate 100. Although in FIG. 10 the third underfill layer 291 and the fourth underfill layer 292 are shown separately, the inventive concept is not limited thereto, and the third underfill layer 291 and the fourth underfill layer 292 may be integrated into a single contiguous underfill layer.

The PIC chip 300 may overlap the EIC chips 200s in the vertical direction. The horizontal surface area of the PIC chip 300 may be greater than the horizontal surface area of each of the EIC chips 200s. In some embodiments, the horizontal surface area of the PIC chip 300 may be greater than the sum of the horizontal surface areas of the EIC chips 200s.

In some embodiments, the second interconnection structure 330 of the PIC chip 300 may be electrically connected to the upper pad 281 of the first EIC chip 201 and the upper pad 282 of the second EIC chip 202 by a connection terminal.

In some embodiments, a redistribution structure may be further provided to be located on the upper surface of the first EIC chip 201 and the upper surface of the second EIC chip 202. The redistribution structure compensates for the difference in vertical level between the upper surface of the first EIC chip 201 and the upper surface of the second EIC chip 202, thereby improving the reliability of electrical connection between the first EIC chip 201 and the second EIC chip 202.

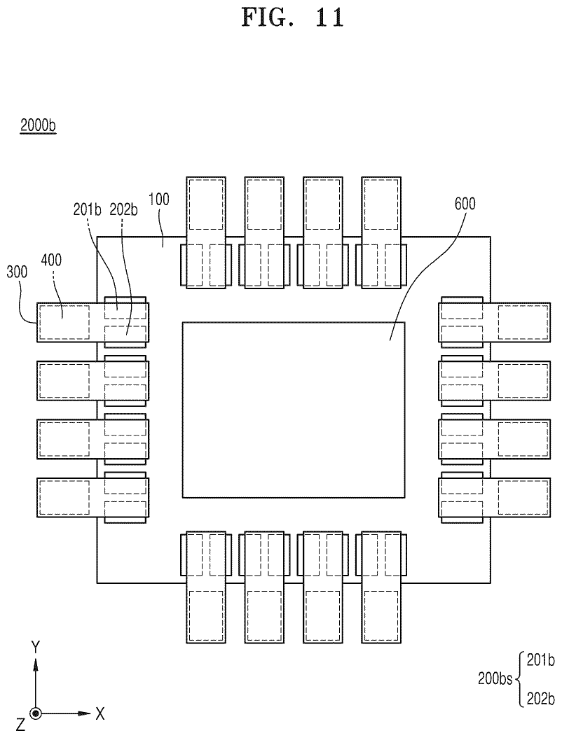

FIG. 11 is a plan view schematically illustrating a semiconductor package 2000b according to an embodiment.

Most of the components constituting the semiconductor package 2000b described below and the materials constituting the components are substantially the same as or similar to those previously described above with reference to FIG. 9. Therefore, for convenience of description, the differences between the semiconductor package 2000 of FIG. 11 and the semiconductor package 2000a of FIG. 9 described above are mainly described.

A plurality of EIC chips 200bs of the semiconductor chip 600 may include a first EIC chip 201b and a second EIC chip 202b. The first EIC chip 201b and the second EIC chip 202b may be located on the lower surface of one PIC chip 300.

In some embodiments, each of the EIC chips 200bs may be located on the upper surface of the package substrate 100. For example, each of the EIC chips 200bs may not protrude from the upper surface of the package substrate 100 planarly.

A portion of each of the first EIC chip 201b and the second EIC chip 202b may not overlap the PIC chip 300 in the vertical direction (the Z direction). For example, each of the first EIC chip 201b and the second EIC chip 202b may protrude out of the lower surface of the PIC chip 300 to the outside of the PIC chip 300 planarly.

In some embodiments, each of the EIC chips 200bs may include a region that overlaps the PIC chip 300 in the vertical direction (the Z direction) and a region that does not overlap the PIC chip 300 in the vertical direction (the Z direction). Each of the EIC chips 200bs may be electrically connected to the interconnection structure of the PIC chip 300 through an upper pad and a connection terminal in a region that overlaps the PIC chip 300 in the vertical direction (the Z direction).

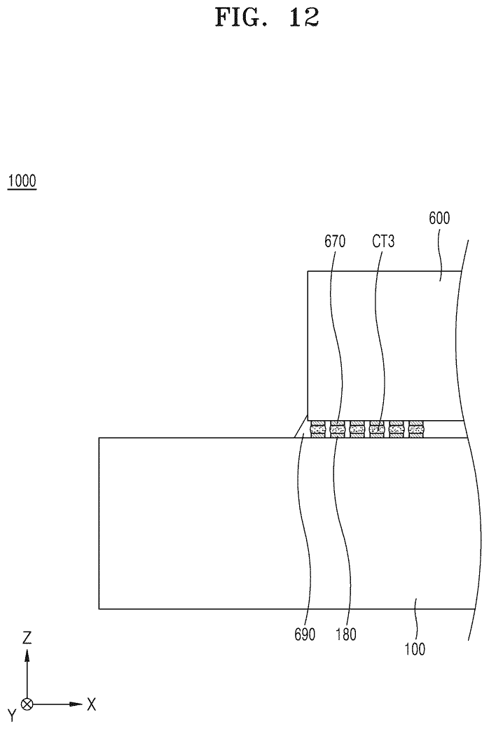

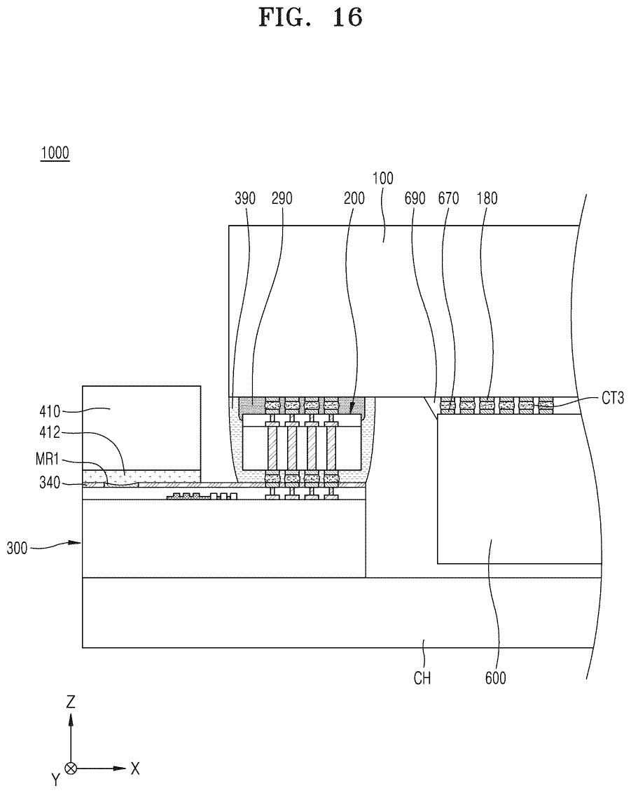

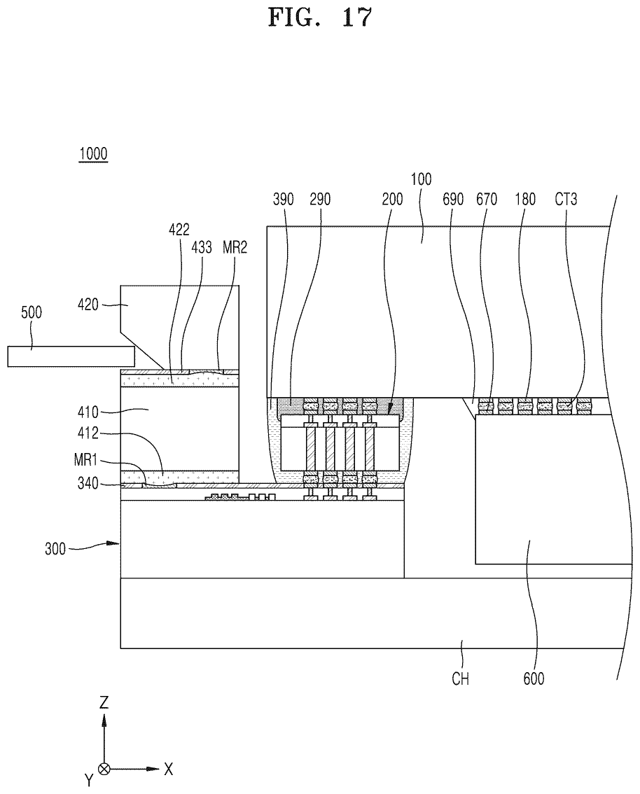

FIGS. 12 to 17 are diagrams illustrating a sequential process of a manufacturing method of the semiconductor package 1000 according to an embodiment. In detail, FIGS. 12 to 17 are cross-sectional views illustrating a portion of the semiconductor package 1000 of FIG. 3 according to a sequential process of the manufacturing method of the semiconductor package 1000.

Referring to FIG. 12, the semiconductor chip 600 may be mounted on the package substrate 100.

The semiconductor chip 600 may be disposed in the center region of the package substrate 100. The connection terminal CT3 that electrically connects the contact pad 670 located on the lower surface of the semiconductor chip 600 to the contact pad 180 of the package substrate 100 may be formed through a reflow process or the like. Next, an underfill layer 690 surrounding the contact pads 670 and 680 of the package substrate 100 and the semiconductor chip 600 and the connection terminal CT3 may be formed through an underfill process.

Although the process in FIG. 12 is shown first, the process sequence in FIG. 12 is not limited thereto. For example, the process of mounting the semiconductor chip 600 on the package substrate 100 may be performed after mounting the EIC chip 200, the PIC chip 300, and the reflective portion 400.

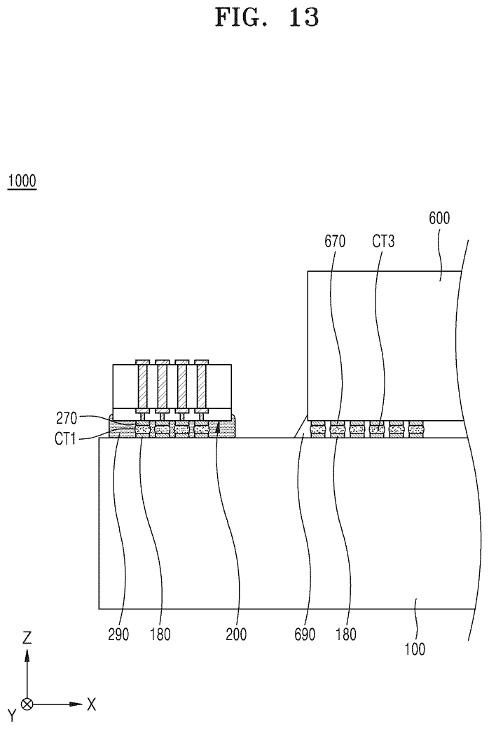

Referring to FIG. 13, the EIC chip 200 may be mounted on the package substrate 100.

The lower pad 270 and the connection terminal CT1 surrounded by an underfill material may be located on the lower surface of the EIC chip 200. The EIC chip 200 may be mounted on the edge region of the package substrate 100 so that the underfill material faces the package substrate 100. Thereafter, the EIC chip 200 may be electrically connected to the package substrate 100 through thermocompression bonding, and the shape of the underfill material may be transformed into the first underfill layer 290.

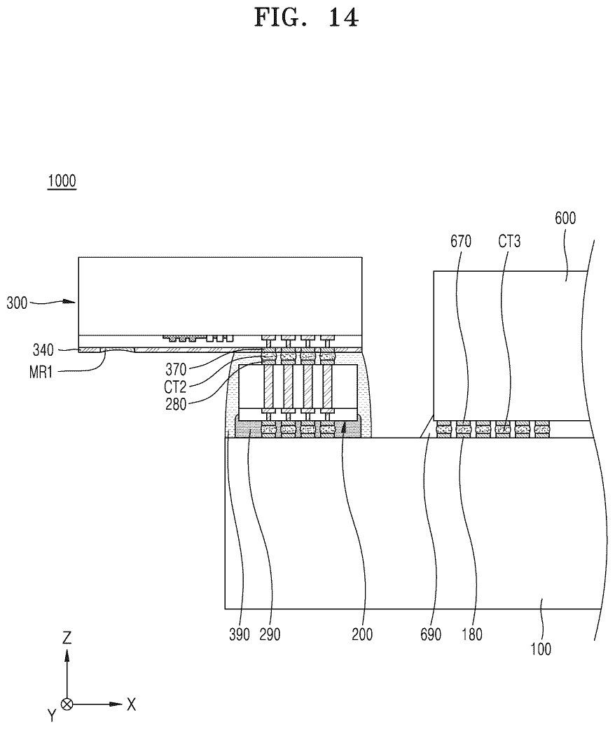

Referring to FIG. 14, the PIC chip 300 may be mounted on the EIC chip 200. The PIC chip 300 may be mounted on the EIC chip 200 so as to protrude out of the EIC chip 200.

After forming the lower pad 370 and the connection terminal CT2 on the lower surface of the PIC chip 300, the PIC chip 300 may be mounted on the EIC chip 200 so that the lower pad 370 may overlap the corresponding upper pad 280 of the EIC chip 200. Next, the PIC chip 300 may be electrically connected to the EIC chip 200 through thermocompression bonding. Thereafter, through an underfill process, a second underfill layer 390 located between the PIC chip 300 and the package substrate 100 may be formed to surround the EIC chip 200.

In some embodiments, in the process of manufacturing the passivation layer 340 surrounding the lower pad 370 of the PIC chip 300, the first mirror MR1 may be formed through a nanoimprint process. In some embodiments, the first mirror MR1 may be formed at a location apart from the lower pad 370 of the PIC chip 300 in the horizontal direction.

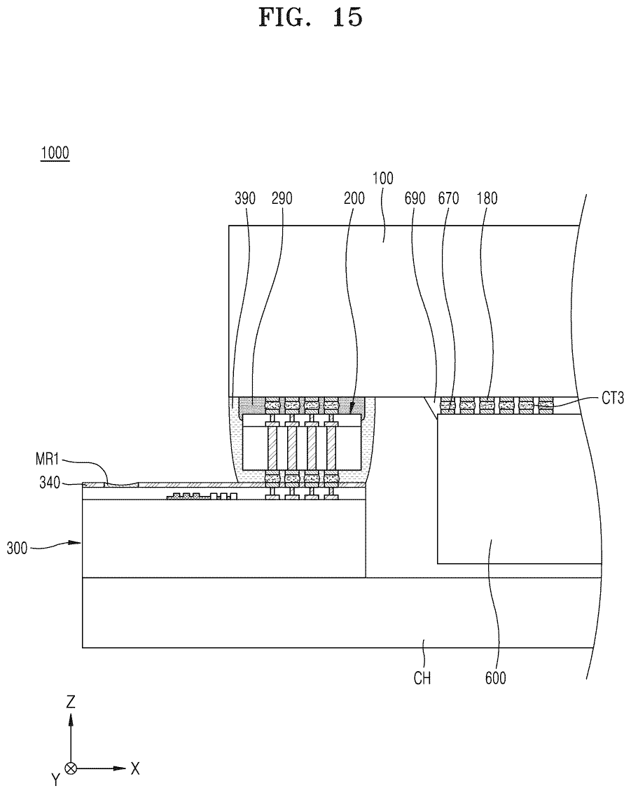

Referring to FIGS. 15 to 17, the result of FIG. 14 may be flipped to attach the reflective portion 400 to the PIC chip 300.

By flipping the result of FIG. 14, the semiconductor package 1000 may be fixed to a support CH. For example, the support CH may be a vacuum chuck. In some embodiments, when the sum of the height of the PIC chip 300 and the height of the EIC chip is greater than the height of the semiconductor chip 600, the PIC chip 300 may physically contact the support CH and the semiconductor package 1000 may be fixed to the support CH by negative pressure formed by the support CH.

Next, the transparent spacer 410 may be attached to the PIC chip 300 using the adhesive layer 412. The transparent spacer 410 and the adhesive layer 412 may include a transparent material that allows photonic signals to pass therethrough. For example, the transparent spacer 410 may include at least one of glass and quartz. The transparent spacer 410 may be apart from the EIC chip 200 in the horizontal direction.

Next, the groove spacer 420 including the second mirror MR2 may be attached to the transparent spacer 410. The groove spacer 420 may be attached to the transparent spacer 410 through the adhesive layer 422. In some embodiments, the adhesive layer 422 may include a transparent component that allows photonic signals to pass therethrough. In some embodiments, the second mirror MR2 may be surrounded by the passivation layer 423 of the groove spacer 420. The second mirror MR2 may be formed through a nanoimprint process. Thereafter, the optical fiber 500 may be inserted into the groove of the groove spacer 420.

While the inventive concept has been particularly shown and described with reference to embodiments thereof, it will be understood that various changes in form and details may be made therein without departing from the spirit and scope of the following claims.

What is claimed is:

1. A semiconductor package comprising:
a package substrate;
a semiconductor chip disposed on an upper surface of the package substrate;
an electronic integrated circuit chip disposed on the package substrate and spaced apart from the semiconductor chip in a horizontal direction parallel to the upper surface of the package substrate;
a photonic integrated circuit chip disposed on an upper surface of the electronic integrated circuit chip, wherein a horizontal surface area of the photonic integrated circuit chip is greater than a horizontal surface area of the electronic integrated circuit chip, and wherein a portion of photonic integrated circuit chip protrudes horizontally from the electronic integrated circuit chip;
a reflective portion disposed on a lower surface of the portion of the photonic integrated circuit chip and spaced apart from the electronic integrated circuit chip in the horizontal direction; and
an optical fiber connected to the reflective portion and spaced apart from the photonic integrated circuit chip in a vertical direction.

2. The semiconductor package of claim 1, wherein
the reflective portion includes a transparent spacer and a groove spacer located on a lower surface of the transparent spacer,
the optical fiber is connected to the groove of the groove spacer, and
a constituent material of the transparent spacer includes at least one of glass and quartz through which a photonic signal passes.

3. The semiconductor package of claim 2, wherein
the reflective portion includes a plurality of mirrors, and
the plurality of mirrors are arranged so that the photonic signal transmitted through the optical fiber is reflected and input to the photonic integrated circuit chip.

4. The semiconductor package of claim 1, wherein the electronic integrated circuit chip is one of a plurality of electronic integrated circuit chips, and the photonic integrated circuit chip is one of a plurality of photonic integrated circuit chips located on upper surfaces of the respective plurality of electronic integrated circuit chips, and
each side of the semiconductor chip faces at least one of the plurality of electronic integrated circuit chips and at least one of the plurality of photonic integrated circuit chips.

5. The semiconductor package of claim 1, wherein a horizontal surface area of the reflective portion is less than the horizontal surface area of the photonic integrated circuit chip.

6. The semiconductor package of claim 1, wherein
the photonic integrated circuit chip includes a first region that overlaps the package substrate in the vertical direction and a second region that does not overlap the package substrate in the vertical direction,
the electronic integrated circuit chip contacts the photonic integrated circuit chip in the first region of the photonic integrated circuit chip, and
the reflective portion contacts the photonic integrated circuit chip in the second region of the photonic integrated circuit chip.

7. The semiconductor package of claim 1, wherein a portion of the electronic integrated circuit chip does not overlap the photonic integrated circuit chip in the vertical direction.

8. The semiconductor package of claim 1, further comprising:
an integrated circuit chip of a different type than the photonic integrated circuit chip and the electronic integrated circuit chip and disposed on the upper surface of the package substrate,
wherein the integrated circuit chip is located between the package substrate and the electronic integrated circuit chip.

9. The semiconductor package of claim 1, wherein
the package substrate includes a center region and an edge region surrounding the center region, and
the semiconductor chip is located in the center region, and the electronic integrated circuit chip is located in the edge region.

10. The semiconductor package of claim 9, wherein a vertical level of an upper surface of the semiconductor chip is lower than or equal to a vertical level of an upper surface of the photonic integrated circuit chip and is higher than a vertical level of the upper surface of the electronic integrated circuit chip.

11. The semiconductor package of claim 1, wherein
the photonic integrated circuit chip is disposed on the electronic integrated circuit chip so that an active surface of the photonic integrated circuit chip faces the electronic integrated circuit chip, and
the electronic integrated circuit chip is disposed on the package substrate so that an active surface of the electronic integrated circuit chip faces the package substrate.

12. The semiconductor package of claim 11, wherein
the electronic integrated circuit chip further includes a through-via, and
the photonic integrated circuit chip is electrically connected to the electronic integrated circuit chip through the through-via.

13. A semiconductor package comprising:
a package substrate;
a semiconductor chip disposed on an upper surface of the package substrate;
a plurality of electronic integrated circuit chips arranged on the package substrate and spaced apart from the semiconductor chip in a horizontal direction;
a photonic integrated circuit chip overlapping the plurality of electronic integrated circuit chips in a vertical direction, wherein a horizontal surface area of the photonic integrated circuit chip is greater than a horizontal surface area of each of the plurality of electronic integrated circuit chips, and a portion of photonic integrated circuit chip protrudes horizontally from the plurality of electronic integrated circuit chips beyond an outer edge of the package substrate;
a reflective portion disposed on a lower surface of the portion of photonic integrated circuit chip and spaced apart from the plurality of electronic integrated circuit chips in the horizontal direction; and
an optical fiber connected to the reflective portion and spaced apart from the photonic integrated circuit chip in the vertical direction,
wherein the plurality of electronic integrated circuit chips are electrically connected to the photonic integrated circuit chip.

14. The semiconductor package of claim 13, wherein a horizontal surface area of the reflective portion is smaller than the horizontal surface area of the photonic integrated circuit chip.

15. The semiconductor package of claim 13, wherein
the plurality of electronic integrated circuit chips are stacked in the vertical direction, and
the photonic integrated circuit chip is disposed on an upper surface of an uppermost electronic integrated circuit chip among the plurality of electronic integrated circuit chips.

16. The semiconductor package of claim 13, wherein
the plurality of electronic integrated circuit chips are arranged side-by-side in the horizontal direction, and
the photonic integrated circuit chip is disposed on upper surfaces of the plurality of electronic integrated circuit chips.

17. The semiconductor package of claim 13, wherein
the photonic integrated circuit chip further includes a grating coupler,
wherein the grating coupler is located in the portion protruding beyond the outer edge of the package substrate.

18. A semiconductor package comprising:
a package substrate;
a semiconductor chip disposed on an upper surface of the package substrate;
a plurality of electronic integrated circuit chips arranged on the package substrate, spaced apart from the semiconductor chip in a horizontal direction, and electrically connected to the semiconductor chip through the package substrate;
a photonic integrated circuit chip overlapping the plurality of electronic integrated circuit chips in a vertical direction, the photonic integrated circuit chip including an opto-electrical conversion unit and have a horizontal surface area that is greater than a horizontal surface area of each of the plurality of electronic integrated circuit chips, wherein a portion of the photonic integrated circuit chip protrudes from the plurality of electronic integrated circuit chips beyond an outer edge of the package substrate;
a reflective portion disposed on a lower surface of portion the photonic integrated circuit chip protruding beyond the outer edge of the package substrate, the reflective portion including a groove spacer including a groove, a transparent spacer, and a plurality of mirrors; and
an optical fiber connected to the groove of the groove spacer of the reflective portion and spaced apart from the photonic integrated circuit chip in the vertical direction,
wherein the plurality of electronic integrated circuit chips are electrically connected to the photonic integrated circuit chip through through-vias located in the plurality of electronic integrated circuit chips.

19. The semiconductor package of claim 18, wherein
an area of an upper surface of the reflective portion is less than an area of an upper surface of the photonic integrated circuit chip,
the reflective portion is spaced apart from the package substrate in the horizontal direction, and
the plurality of mirrors are arranged so that a photonic signal incident on the reflective portion is reflected and incident on the opto-electrical conversion unit.

20. The semiconductor package of claim 18, wherein
each of the plurality of electronic integrated circuit chips is disposed on the package substrate so that an active surface of each of the plurality of electronic integrated circuit chips faces the package substrate, and
the photonic integrated circuit chip is disposed on the package substrate so that an active surface of the photonic integrated circuit chip faces the package substrate, and is in direct contact with at least one of the plurality of electronic integrated circuit chips.
